(19) United States
(12) Patent Application Publication
(10) Pub. No.: US 2011/0259393 A1
(43) Pub. Date: Oct. 27, 2011

(54) COLLAPSIBLE SOLAR CELL MODULE

(75) Inventors: CHIH-MING LAI, Chu-Nan (TW); RONG-YIH YAN, Chu-Nan (TW)

(73) Assignee: FOXSEMICON INTEGRATED TECHNOLOGY, INC., Chu-Nan (TW)

(21) Appl. No.: 12/854,182

(22) Filed: Aug. 11, 2010

(30) Foreign Application Priority Data
Apr. 23, 2010 (CN) 201020168974.8

(51) Int. Cl. H01L 31/045

(52) U.S. Cl. 136/245

(57) ABSTRACT

A solar cell module includes a number of solar cell panels and a number of connecting elements connecting to the solar cell panels. The solar cell panels are collapsibly connected by the connecting elements. Due to the collapsible function, a volume of the solar cell module can be reduced, thereby simplifying transport of the solar cell module.

### BACKGROUND

1. Technical Field

The present disclosure generally relates to solar cell modules, and particularly to a collapsible solar cell module with collapsible connecting element.

2. Description of the Related Art

Solar cells, utilizing solar radiation to generate clean and renewable energy, have gained massive popularity in use ranging from residential to large scale industrial application. Although solar cells have gradually improved efficiency of conversion, arrays presenting a very large area are still required to fulfill power requirements.

Standalone power supply systems, which can fully generate electric power from received sunlight, have been developed, often including a solar cell module, a rechargeable battery, a controller controlling the solar cell module and rechargeable battery, and an AC electric load connected to the controller. These components are independent of each other, and connected together by electrical interconnections.

It is difficult to transport the standalone power supply system for temporary deployment and relocation. Also, the solar cell module is often immovably fixed to a base or frame, making it difficult to change alignment of the solar receiving surface.

What is needed, therefore, is a solar cell module which can collapse easily for transport and ameliorate the described limitations.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present solar cell module. Moreover, in the drawings, like reference numerals designate corresponding parts throughout the views.

FIG. 1 is a schematic view of a solar cell module collapsed in accordance with a first embodiment.

FIG. 2 is a schematic view of a solar cell module deployed in accordance with the first embodiment.

FIG. 3 is a schematic view of a solar cell module collapsed in accordance with a second embodiment.

FIG. 4 is a schematic view of a solar cell module deployed in accordance with the second embodiment.

FIG. 5 is a schematic view of a solar cell module collapsed in accordance with a third embodiment.

FIG. 6 is a schematic view of a solar cell module deployed in accordance with the third embodiment.

FIG. 7 is a schematic view of a solar cell module collapsed in accordance with a fourth embodiment.

FIG. 8 is a schematic view of a solar cell module deployed in accordance with the fourth embodiment.

FIG. 9 is a schematic view of a solar cell module collapsed in accordance with a fifth embodiment.

FIG. 10 is a schematic view of a solar cell module deployed in accordance with the fifth embodiment.

### DETAILED DESCRIPTION

Embodiments of a solar cell module as disclosed are described in detail here with reference to the drawings.

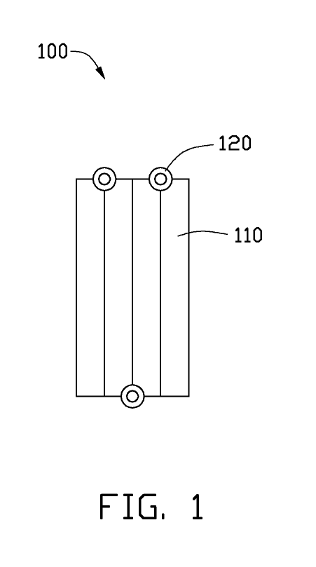

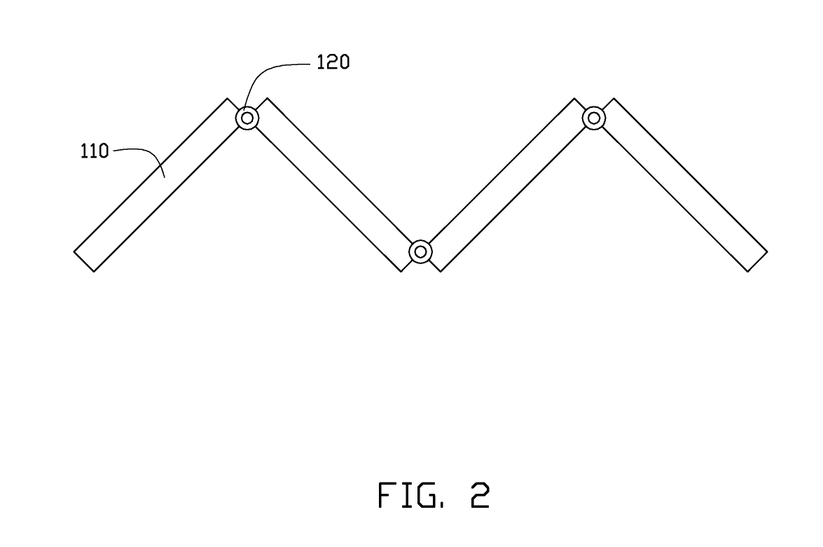

Referring to FIG. 1 and FIG. 2, a solar cell module 100 in accordance with a first embodiment includes a plurality of solar cell panels 110 and a plurality of connecting elements 120. In this embodiment, the connecting elements 120 are pivoting structures and at least one connecting element 120 is arranged between the adjacent solar cell panels 110 for collapsing together with the connecting elements 120. The connecting elements 120 are staggered, and can be hinges.

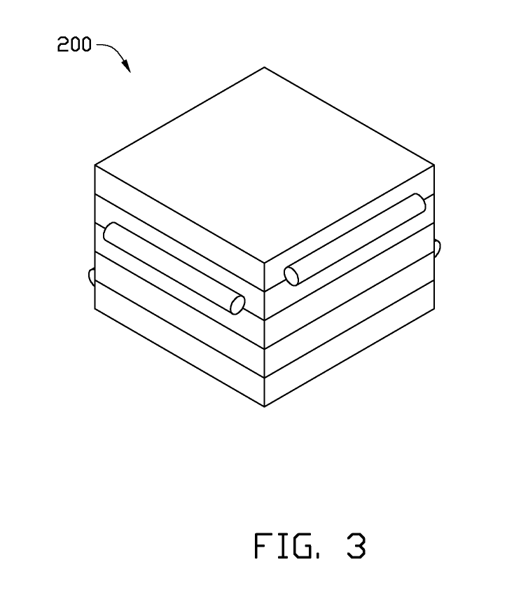

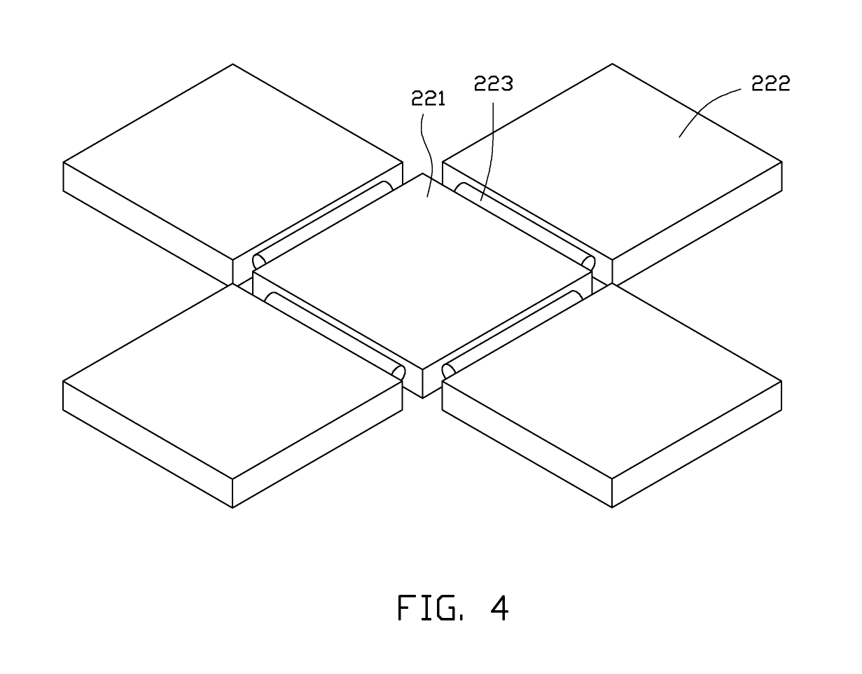

Referring to FIG. 3 and FIG. 4, a solar cell module 200 in accordance with a second embodiment includes a main bottom solar cell panel 221, a plurality of peripheral solar cell panels 222 surrounding the main bottom solar cell panel 221, and a plurality of elastic connecting elements 223 connecting the side surfaces of the main bottom solar cell panel 221 and the plurality of peripheral solar cell panels 222. As an example, the main bottom solar cell panel 221 and the plurality of peripheral solar cell panels 222 can be quadrate plates with four peripheral solar cell panels 222 and elastic connecting elements 223 utilized.

FIG. 4 schematically shows the elastic connecting elements 223. In the practical embodiment, the elastic connecting elements 223 collapsibly connect the main bottom solar cell panel 221 and the peripheral solar cell panels 222, and extend elastically when the solar cell module 200 is not in use, and the four elastic connecting elements 223 assume different degrees of deformation to stack the corresponding peripheral solar cell panel 222 on the top surface of the main bottom solar cell panel 221. Further, to provide support for the peripheral solar cell panels 222 when the solar cell module 200 is in use, the elastic connecting elements 223 return from deformation and spread the peripheral solar cell panels 222 with the main bottom solar cell panel 221, maintaining the same plane.

A supporting mechanism can be arranged outside the solar cell module 200 or between the main bottom solar cell panel 221 and the peripheral solar cell panels 222, with the structure and number of main bottom solar cell panels 221, peripheral solar cell panels 222, and elastic connecting elements 223 adjusted according to need as long as the solar cell module 200 can be deployed for use and collapsed for convenient transport and storage.

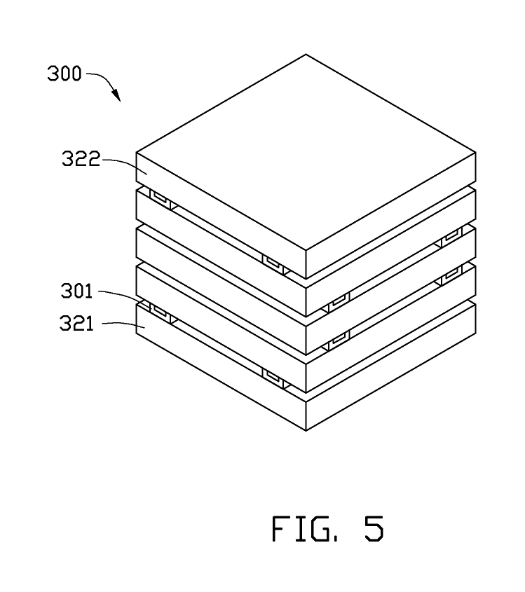

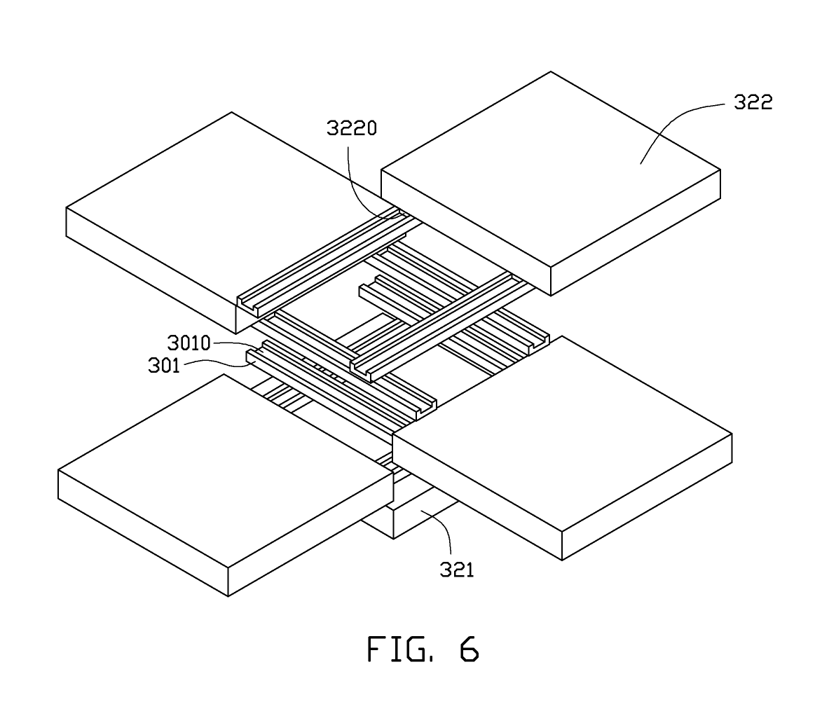

Referring to FIG. 5 and FIG. 6, a solar cell module 300 in accordance with a third embodiment includes a main bottom solar cell panel 321, a plurality of peripheral solar cell panels 322, and rail structures 301 for connecting slidably with each peripheral solar cell panels 322. In this embodiment, four peripheral solar cell panels 322 are arranged above the main bottom solar cell panel 321 at different heights and four rail structures 301 are correspondingly arranged above the main bottom solar cell panel 321 horizontally at different heights. Each of the peripheral solar cell panels 322 slidably matches ridges and recesses with the corresponding rail structure 301. For example, the bottom of each peripheral solar cell panel 322 can be configured with a longitudinal ridge 3220, and the rail structure 301 includes a longitudinal recession 3010 receiving the ridge 3220. In contrast, if the bottom of each peripheral solar cell 322 is configured with a longitudinal recession, the rail structure 301 will include a corresponding longitudinal ridge. When the solar cell module 300 is deployed, the plurality of peripheral solar cell panels 322 slides outwardly along the rail structure 301 horizontally. When the solar cell module 300 is stacked, the plurality of peripheral solar cell panels 322 slide inwardly along the rail structure 301 horizontally and stack above the main bottom solar cell panel 321 sequentially. A supporting mechanism for supporting the outside portion of the peripheral solar cell panel 322 can be arranged to stably fix the peripheral solar cell panel 322 in the rail structure 301 when deployed. There is no limitation of the manner of the supporting mechanism.

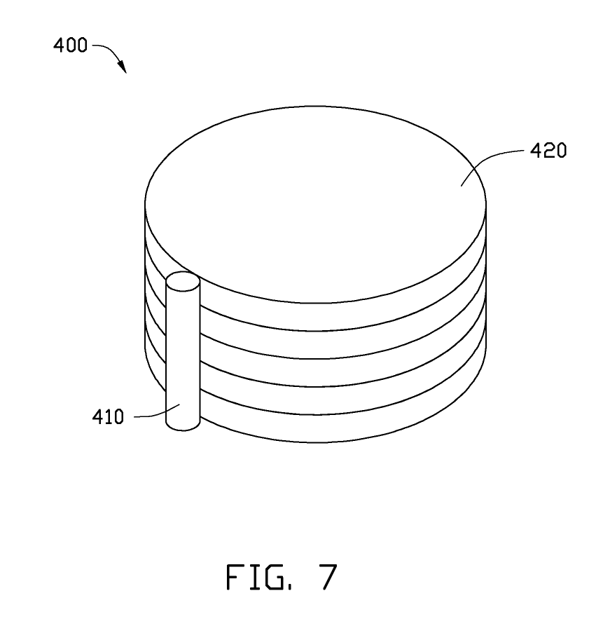

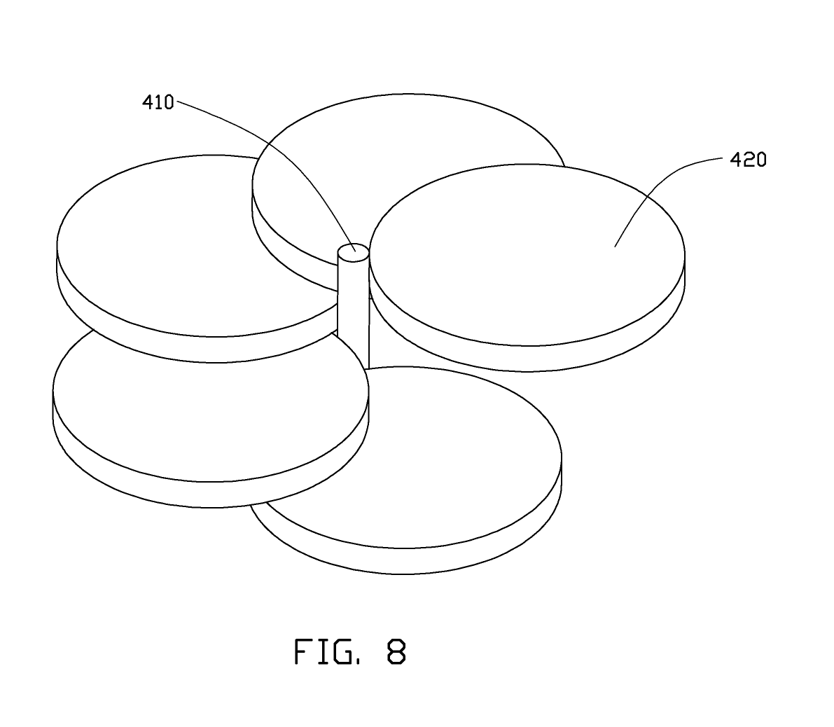

Referring to FIG. 7 and FIG. 8, a solar cell module 400 in accordance with a fourth embodiment includes a supporting shaft 410 and a plurality of solar cell panels 420 connecting the supporting shaft 410. The plurality of solar cell panels 420 is arranged parallel along the longitudinal axis of the supporting shaft 410. The plurality of solar cell panels 420 is planar and connects with the supporting shaft 410 perpendicularly, rotatable horizontally by any angle. When the solar cell module 400 is deployed, the plurality of solar cell panels 420 can rotate horizontally by different angle to stagger each other as shown in FIG. 8 to receive sunlight with larger area. When the solar cell module 400 is stacked, the plurality of solar cell panels 420 rotate horizontally to the same side of the supporting shaft 410 and stack together.

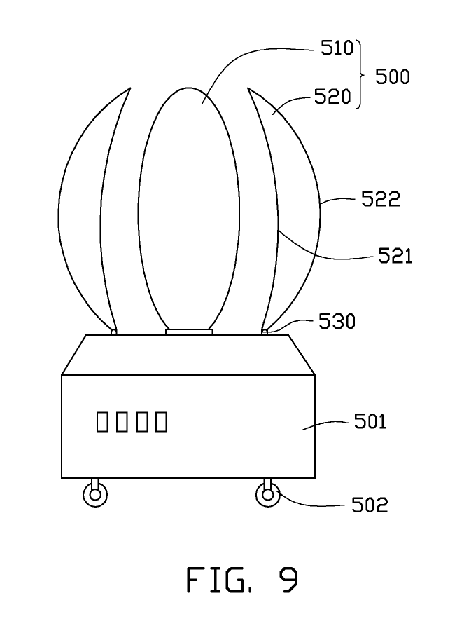

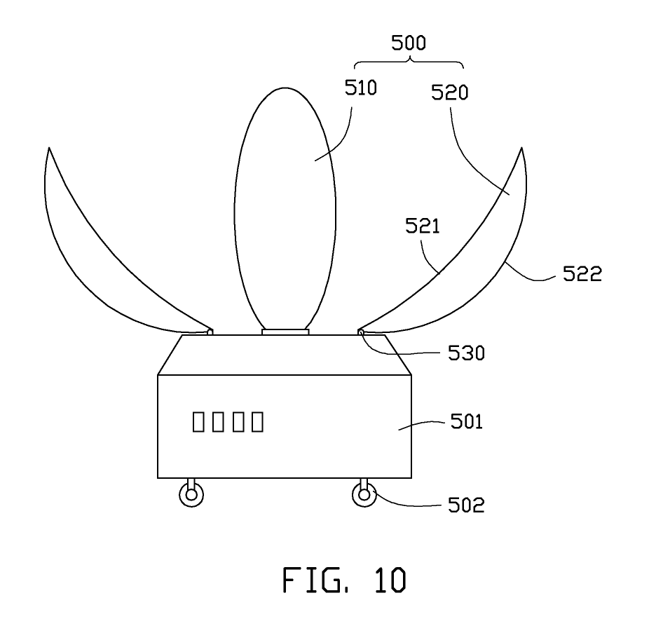

Referring to FIG. 9 and FIG. 10, a solar cell module 500 in accordance with a fifth embodiment includes a central solar cell panel 510 surrounded by a plurality of peripheral solar cell panels 520. The central solar cell panel 510 forms an elliptical sphere and each peripheral solar cell panel 520 includes an inner surface 521 parallel to the outer surface of the elliptical sphere and an outer surface 522 with curvature exceeding that of the inner surface 521. In this embodiment, the solar cell module 500 is integrated with a portable solar cell power supply device, and arranged on an electricity module 501. Each peripheral solar cell panel 520 is rotatably fixed on the top surface of the electricity module 501 with a hinged body 530. The hinged body 530 allows the peripheral solar cell panels 520 to rotate a predetermined angle along a predetermined path. When the solar cell module 500 is in use, it rotates the peripheral solar cell panels 520 incline outwardly relative to the central solar cell panel 510 to receive sunlight with a total area. When the solar cell module 500 is not in use, it rotates the peripheral solar cell panels 520 to incline inwardly toward the central solar cell panel 510 to reduce the volume of the total solar cell module 500. A plurality of rollers 502 is arranged at the bottom of the electricity module 501 to conveniently transport the portable solar cell power supply device.

It is to be understood, however, that even though numerous characteristics and advantages of the disclosure have been set forth in the foregoing description, together with details of the structures and functions of the embodiment(s), the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A solar cell module comprising:
a plurality of solar cell panels; and
a plurality of connecting elements, wherein the plurality of solar cell panels is collapsibly connected together by the plurality of connecting elements.

2. The solar cell module as claimed in claim 1, wherein the plurality of connecting elements is pivoting structures and adjacent ones of the solar cell panels are connected by at least one of the pivoting structures to collapse the plurality of solar cell panels by sequence.

3. The solar cell module as claimed in claim 1, wherein the plurality of solar cell panels comprise a main bottom solar cell panel and multiple peripheral solar cell panels connected around the main bottom solar cell panel by the plurality of connecting elements.

4. The solar cell module as claimed in claim 3, wherein the plurality of connecting elements is contractile.

5. The solar cell module as claimed in claim 3, wherein the plurality of solar cell panels slidably connect to a main bottom solar cell panel through a rail structure.

6. The solar cell module as claimed in claim 1, further comprising a supporting shaft for connecting the plurality of solar cell panels arranged axially and hinged through the connecting element.

7. The solar cell module as claimed in claim 6, wherein the plurality of solar cell panels hinges perpendicular to the supporting shaft.

8. The solar cell module as claimed in claim 7, wherein the plurality of solar cell panels is rotatably fixed with the supporting shaft on a plane perpendicular to the supporting shaft.

9. The solar cell module as claimed in claim 1, wherein the plurality of solar cell panels includes a central panel and multiple peripheral panels surrounding the central panel, wherein the peripheral panels are pivotable inwardly or outwardly relative to the central panel by a predetermined angle.

10. The solar cell module as claimed in claim 9, wherein the central panel forms an elliptical sphere and each peripheral panel includes an inner surface parallel to the outer surface of the elliptical sphere and an outer surface with curvature exceeding that of the inner surface.
